(19) United States
(12) Patent Application Publication
(10) Pub. No.: US 2026/0096432 A1
(43) Pub. Date: Apr. 2, 2026

(54) MULTI-STAGE, SPRING-LOADED FASTENER ASSEMBLY

(71) Applicant: Arista Networks, Inc., Santa Clara, CA (US)

(72) Inventors: Daehwan Daniel Kim, Sunnyvale, CA (US); Steven Alf Hanssen, San Jose, CA (US); Robert Morris Wilcox, Saratoga, CA (US); Richard Neville Hibbs, Carmel, CA (US); Xin Xue, San Jose, CA (US); Tiffany Doria, Fremont, CA (US); Carlos Daniel Alvizo Flores, Zapopan (MX)

(21) Appl. No.: 18/900,136

(22) Filed: Sep. 27, 2024

(51) Int. Cl. H01L 23/40

(52) U.S. Cl. CPC H10W 40/641

(57) ABSTRACT

A multi-stage, spring-loaded fastener assembly comprises a spring-loaded fastener and a fastener cap. The spring-loaded fastener includes a fastener head, a fastener body that extends from the fastener head to a distal end, a pressure plate, and a compression spring disposed between the fastener head and the pressure plate and operatively coupled to the pressure plate to assert a force on the pressure plate in a first direction. The fastener cap comprises a head portion and a body portion. The fastener cap is coupled to the fastener head of the spring-loaded fastener. The body portion extends toward the pressure plate and is operatively coupled to the pressure plate to resist movement of the pressure plate in a second direction that is opposite to the first direction.

### BACKGROUND

Semiconductor chips generate heat that can degrade performance and reliability. Heatsinks are widely used to dissipate heat from processors and other chips. A thermal interface material (TIM) is applied between the chip die and heatsink pedestal. The TIM may become more viscous when it is heated.

Larger heatsinks are attached to the underlying printed circuit board (PCB) or through the PCB to a backplane using a variety of attachment mechanisms, such as screws, pushpins, clamps, or other fasteners, to apply a force on to the heatsink and compress the TIM and achieve a desired thermal gap between the heatsink and chip.

As processors have become ever more powerful, heatsinks have become significantly larger and heavier. With a heavier heatsink, shock and vibration can cause the heatsink to move, resulting in separation, cracking, or the formation of air voids in the TIM. When this occurs, the system incorporating the heatsink may not be able to start without the TIM being retreated.

To address this problem, electronics manufacturers are applying ever increasing clamping forces to hold heatsinks in place. Care must be taken, however, not to exceed the chip's recommended long term compression force. For heavier heatsinks, the chip's recommended long term compression force may be insufficient to prevent the types of movement that can cause separation, cracking, or air voids.

### BRIEF DESCRIPTION OF THE DRAWINGS

The drawings accompanying and forming part of this specification are included to depict certain aspects of the invention. A clearer impression of the invention, and of the components and operation of systems provided with the invention, will become more readily apparent by referring to the exemplary, and therefore non-limiting, embodiments illustrated in the drawings, wherein identical reference numerals designate the same components. Note that the features illustrated in the drawings are not necessarily drawn to scale.

FIG. 1 is a diagrammatic representation of a cross-sectional view of one embodiment of a system using multi-stage, spring-loaded fasteners.

FIG. 2 is a diagrammatic representation of a cross-sectional view of one embodiment of a multi-stage, spring-loaded fastener assembly.

FIG. 3 is a diagrammatic representation of an end view of one embodiment of a multi-stage, spring-loaded fastener assembly.

FIG. 4 is a diagrammatic representation of a cross-sectional view of one embodiment of a fastener.

FIG. 5 is a diagrammatic representation of a cross-sectional view of one embodiment of a fastener cap.

FIG. 6 is a diagrammatic representation of a cross-sectional view of one embodiment of a spring-loaded fastener.

FIG. 7 is a flow diagram of one embodiment of a method for assembling electronic components.

### WRITTEN DESCRIPTION

Embodiments and the various features and advantageous details thereof are explained more fully with reference to the non-limiting embodiments that are illustrated in the accompanying drawings and detailed in the following description. Descriptions of well-known starting materials, processing techniques, components and equipment are omitted so as not to unnecessarily obscure the embodiments in detail. It should be understood, however, that the detailed description and the specific examples are given by way of illustration only and not by way of limitation. Various substitutions, modifications, additions and/or rearrangements within the spirit and/or scope of the underlying inventive concept will become apparent to those skilled in the art from this disclosure.

Embodiments of the present disclosure provide spring-loaded fastener assemblies that can be used, for example, to constrain a heatsink's position during vibration or shock events and thereby reduce or avoid separation, cracking, or air voids in the thermal interface material (TIM). Thus, a system can start up after a shock event without requiring retreatment of the TIM.

According to one embodiment, a spring-loaded fastener assembly includes a fastener, a pressure plate, a compression spring between the fastener and the pressure plate, and a fastener cap. The fastener cap is coupled to the fastener and contacts or otherwise asserts a force on the pressure plate. Thus, when the heatsink tries to move away from the underlying chip, movement of the pressure plate is constrained not only by the compression spring, but also by the more rigid structure provided by the fastener cap.

One embodiment of a multi-stage, spring-loaded fastener assembly comprises a spring-loaded fastener and a fastener cap. The spring-loaded fastener comprises a fastener having a fastener head and a fastener body, a pressure plate, and a compression spring disposed between the fastener head and the pressure plate and operatively coupled to the pressure plate to assert a force on the pressure plate in a first direction. The fastener cap, according to one embodiment, comprises a head portion and a body portion. The head portion of the fastener cap is coupled to the head of the spring-loaded fastener. The body portion of the fastener cap extends toward the pressure plate and is operatively coupled to the pressure plate to resist movement of the pressure plate in a direction opposite to the direction of the spring force applied by the compression spring to the pressure plate.

Embodiments also include multi-stage, spring-loaded fastener kits that include, for example, a fastener, a pressure plate, a compression spring, and a fastener cap. The fastener may include a fastener head and a fastener body. The compression spring is sized to fit over the fastener body and be compressed between the fastener and the pressure plate to assert a force on the pressure plate in a first direction. The fastener cap comprises a head portion and a body portion. The fastener cap is adapted to be installed on the fastener with the body portion extending toward and operatively coupled to the pressure plate to resist motion of the pressure plate in a direction opposite to direction of the spring force applied by the compression spring to the pressure plate.

According to one embodiment, the fastener cap is installed on the head of the fastener. For example, the head of the spring-loaded fastener may have external threads and the fastener cap may have a threaded opening with internal threads to receive and engage with the head of the spring-loaded fastener.

The fastener and fastener cap include features to facilitate driving of the fastener and fastener cap. In one embodiment, the fastener head defines a shaped recess to receive a first tool to facilitate driving of the spring-loaded fastener and the fastener cap has an outer profile that is shaped to mate with a second tool to facilitate installation of the fastener cap.

In one embodiment, the body portion of the fastener cap defines a cavity in which the compression spring and a portion of the fastener body are disposed. The compression spring may, for example, be disposed between the fastener body and the body portion of the fastener cap.

The fastener body, according to one embodiment, has a cylindrical outer profile with a diameter that may vary along the length of the body portion. The body portion of the fastener cap may have an inner diameter that is larger than the outer diameter of the fastener body to create a gap between the fastener body and the fastener cap.

Embodiments also include methods for installing components. One embodiment includes installing a spring-loaded fastener on a heatsink, positioning the heatsink on the electronic component, fastening the spring-loaded fastener to compress a compression spring that asserts a force on a pressure plate in a first direction, and installing a fastener cap on the spring-loaded fastener. According to one embodiment, the installed fastener cap comprises a head portion coupled to the head of the spring-loaded fastener and a body portion extending toward the pressure plate and operatively coupled to the pressure plate to resist movement of the pressure plate in a second direction that is opposite to the first direction. According to one embodiment, installing the fastener cap on the spring-loaded fastener comprises driving the fastener cap until a specified torque is reached.

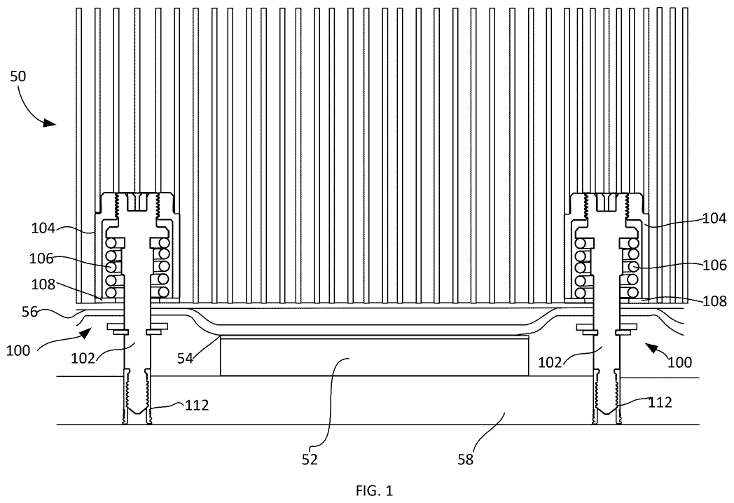

FIG. 1 is a diagrammatic representation of one embodiment of an assembly comprising multi-stage, spring-loaded fastener assemblies 100 that apply a compression force to heatsink 50 to bias heatsink 50 toward semiconductor chip 52 to compress TIM 54. The multi-stage, spring-loaded fastener assemblies 100 include spring-loaded fasteners 102 that pass through the base 56 of heatsink 50 to screw into or otherwise engage with fastener receivers 112 disposed in PCB 58 or a supportive backplane. Fasteners 102 compress springs 106 which apply a force square to heatsink base 56. This compression force is distributed over a larger area by pressure plates 108. Fastener caps 104 are placed over fasteners 102 and also contact or are otherwise operatively coupled to pressure plates 108.

Vibration or a shock event may result in a force being applied to heatsink 50 in a direction to move heatsink 50 away from chip 52. Movement of heatsink 50 away from chip 52 is resisted, however, not only by springs 106, but also by the more rigid structures of fastener caps 104. More particularly, fastener caps 104 help resist the movement of pressure plates 108, and hence heatsink 50, in the direction opposite to the spring force applied by compression springs 106 to pressure plates 108.

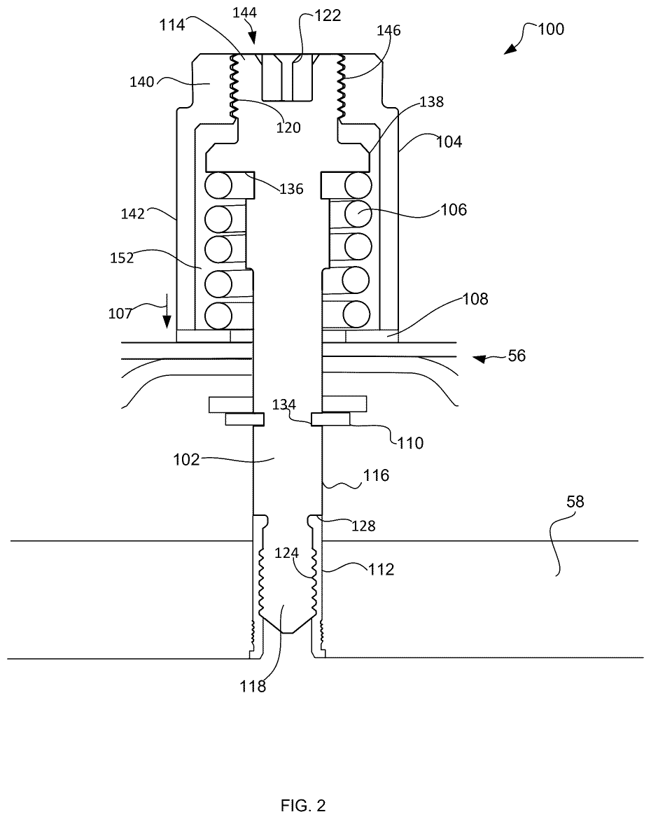

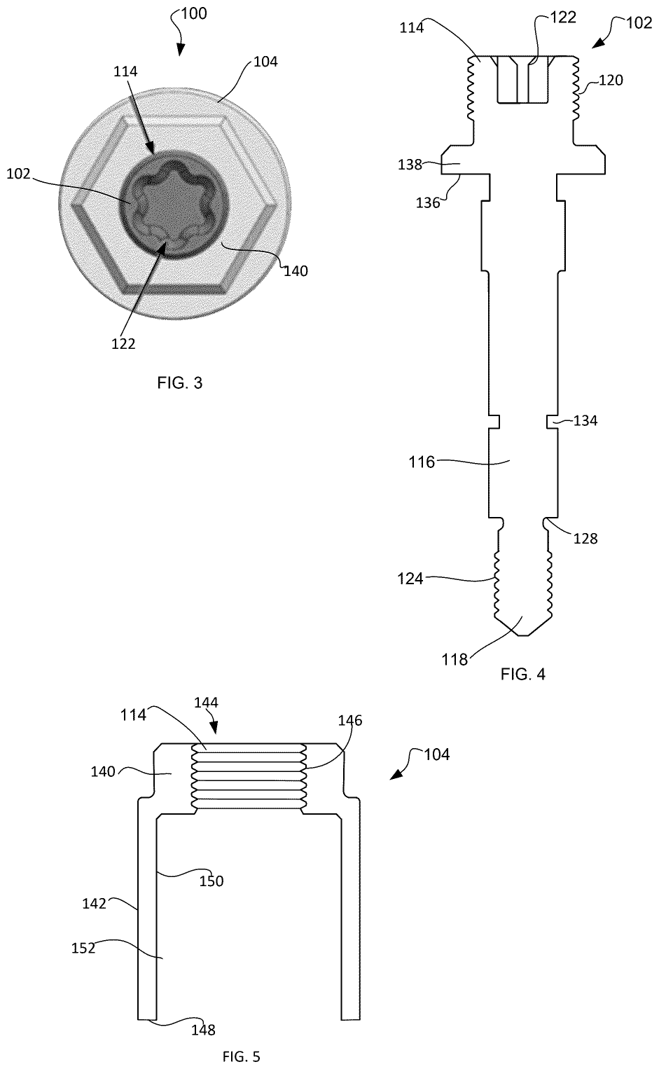

FIG. 2 is a diagrammatic representation of one embodiment of a multi-stage, spring-loaded fastener assembly. FIG. 3 is a diagrammatic representation of an end view of one embodiment of a multi-stage, spring-loaded fastener assembly 100. FIG. 4 is a diagrammatic representation of one embodiment of fastener 102. FIG. 5 is a diagrammatic representation of one embodiment of fastener cap 104.

Fastener assembly 100 comprises a fastener 102 and a fastener cap 104, a compression spring 106, a pressure plate 108 and a retaining member 110. Fastener 102 is a spring-loaded fastener that can be fastened to or otherwise engaged with fastener receiver 112 to compress spring 106, which asserts a force in a first direction 107 (FIG. 2) on pressure plate 108. Pressure plate 108 distributes the force to heatsink base 56. Fastener cap 104, in combination with spring 106 in some embodiments, resists movement of pressure plate 108 in the opposite direction and, hence, movement of the heatsink that might cause separation, cracking, or air voids in the TIM (e.g., TIM 54 of FIG. 1).

Fastener 102 comprises a fastener head 114 and a longitudinally extending fastener body 116 (e.g., a shaft) that extends from fastener head 114 to a distal tip portion 118. Fastener head 114 comprises a threaded portion with a length of external threads 120 that are adapted to engage with internal threads 146 of fastener cap 104. Thus, fastener cap 104 screws onto fastener head 114 and provides a more rigid structure than spring 106 to resist movement against the compression force asserted by fastener assembly 100. According to one embodiment, the longitudinal axes of fastener 102, fastener cap 104, and spring 106 are coaxial when fastener cap 104 is installed.

Fastener head 114 comprises a tool engagement area 122 for engaging with a suitably sized and shaped tool to facilitate driving fastener 102, such as by pushing or rotating fastener 102. Tool engagement area 122, according to one embodiment, comprises a shaped recess that accepts the end of a tool. By way of example, but not limitation, the recess may be a slot compatible with a flat-head driver, a cross-shaped recess compatible with a Phillips head driver, a hexagonally shaped recess compatible with a hex head driver, or a star-shaped recess compatible with a star head driver. According to one embodiment, fastener 102 is a screw and, as such, tool engagement area 122 facilitates rotation of fastener 102 with a suitably sized and shaped tool. In some embodiments, tool engagement area 122 of fastener 102 remains exposed when fastener cap 104 is installed.

Fastener body 116 may have a variety of form factors and features to engage with a compatible receiver 112, including, but not limited to, receivers widely used in the industry. Fastener body 116, according to one embodiment, has a cylindrical profile with an outer diameter that may vary along the length of fastener body 116. In the illustrated embodiment, fastener body 116 comprises external threads 124 (e.g., at tip portion 118), and fastener receiver 112 is an internally threaded boss, standoff, or other component with internal threads to receive and engage with the threads of fastener body 116. According to another example embodiment, fastener 102 is a push pin and fastener receiver 112 is a push pin receiver, such as clip or socket into which the pushpin snaps.

In some embodiments, fastener 102 or receiver 112 has features to limit the depth to which fastener 102 can be driven. For example, fastener body 116 includes a depth control shoulder 128 that bottoms out on a facing surface of receiver 112 to limit the depth that fastener 102 can be driven. In addition, or in the alternative, receiver 112 may have threads machined to a specific depth to cause fastener 102 to bottom out at a desired position.

One or more of fastener 102 or receiver 112 may include anti-backout features to prevent fastener 102 from backing out of receiver 112 when fully engaged. Examples of anti-backout features include, but are not limited to indents and detents, threads that deform to prevent backout, or other features to resist fastener 102 backing out from receiver 112 when fastener 102 is fully engaged (fully screwed in).

Prior to fastener 102 being engaged by receiver 112, fastener 102 may fall out of the openings through heatsink base 56. To prevent this, a retaining mechanism may be provided. In the embodiment illustrated, for example, fastener body 116 includes a circumferential channel 134 in which retaining member 110 is disposed. Retaining member 110 is too large to fit through the opening in heatsink base 56 through which fastener body 116 passes and thus prevents fastener 102 from falling out.

Fastener 102 comprises a spring compression shoulder 136 that is operatively coupled to spring 106 to assert a compression force on spring 106 to compress spring 106 between compression shoulder 136 and pressure plate 108. According to one embodiment, spring compression shoulder 136 abuts spring 106. In another embodiment, compression force is transferred from spring compression shoulder 136 to spring 106 through an intermediate structure that transfers force from spring compression shoulder 136 to spring 106. In the illustrated embodiment, a radial flange 138 disposed at the base of fastener head 114 provides spring compression shoulder 136. In another embodiment, radial flange 138 or other feature that defines a spring compression shoulder is spaced from fastener head 114 along fastener body 116.

Fastener cap 104 comprises a head portion 140 and a body portion 142 that extends from head portion 140 only part way along the length of fastener body 116. Head portion 140 defines a fastener head receiving opening 144 having internal threads 146 to engage external threads 120 of fastener head 114. According to one embodiment, head portion 140 screws onto fastener 102 in the same direction that fastener screws into fastener receiver 112 (e.g., clockwise or anticlockwise). Thus, installing fastener cap 104 onto fastener 102 will not cause fastener 102 to back out of receiver 112.

Body portion 142 extends from head portion 140 to a distal end 148 (FIG. 5) that abuts pressure plate 108 or an intermediate structure through which force can be transferred between pressure plate 108 and body portion 142 and provides additional rigidity to resist movement of pressure plate 108 and, hence, the heatsink compared to compression spring 106 alone. As fastener cap 104 may be used to provide additional rigidity to resist movement of the heatsink, fastener cap 104 is therefore preferably formed of a rigid plastic, metal, or another rigid material or combinations thereof.

Body portion 142 may have a variety of form factors. Body portion 142, according to one embodiment, comprises a wall with an inner surface 150 (FIG. 5) that defines a cavity 152 in which spring 106 and a portion of fastener body 116 are disposed when fastener cap 104 is installed. In an even more particular embodiment, the wall is a cylindrical wall having an inner diameter that is greater than the outer diameter of body portion 116 to leave a gap therebetween. The wall may be solid or include openings therethrough.

Fastener cap 104 may include features to facilitate rotating fastener cap 104. According to one embodiment, the external profile of head portion 140 is shaped to allow a tool such as a socket or wrench to engage and drive fastener cap 104. In an even more particular embodiment, head portion 140 is shaped to mate with a hex socket or hex wrench (FIG. 3).

Fastener cap 104, when installed, is operatively coupled to pressure plate 108 to assert a force on pressure plate 108. More particularly, when installed, the end of body portion 142 contacts pressure plate 108 or an intermediate structure that transfers force from body portion 142 to pressure plate 108. Preferably, body portion 142 contacts pressure plate 108 evenly about fastener body 116 or otherwise asserts even pressure on pressure plate 108 about fastener body 116.

Spring 106 is operatively coupled to spring compression shoulder 136 and pressure plate 108. Spring 106 may abut spring compression shoulder 136 and pressure plate 108 or may abut intermediate structures that transfers force from spring compression shoulder 136 to spring 106 or from spring 106 to pressure plate 108. In one embodiment, compression spring 106 is a helical spring through which fastener body 116 passes.

Pressure plate 108 is operatively coupled to spring 106 and body portion 142. For example, pressure plate 108 may abut spring 106 and end 148 of body portion 142. In another embodiment, force from spring 106 or body portion 142 is transferred to pressure plate 108 through an intermediate structure. Pressure plate 108 serves to distribute pressure across a greater area of heatsink base 56 or another component being secured. In one embodiment, pressure plate 108 comprises a washer.

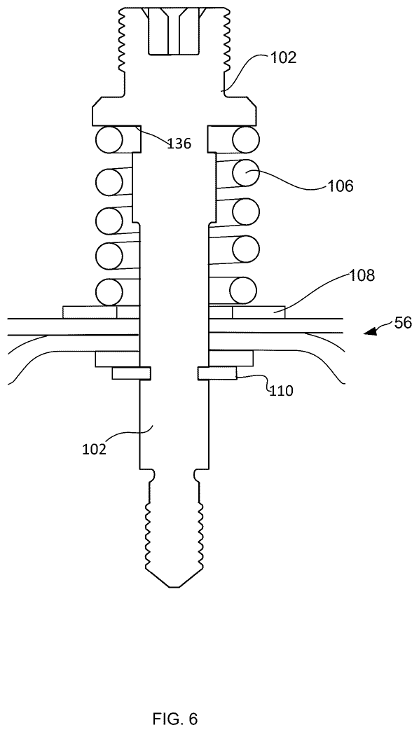

FIG. 6 is a diagrammatic representation of a spring-loaded fastener 102 installed in an opening through heatsink base 56, with compression spring 106 disposed between spring compression shoulder 136 and pressure plate 108. Retaining member 110 helps retain spring-loaded fastener 102 in the opening. Fastener 102 can be aligned with a compatible receiver (e.g., receiver 112) and engaged with the receiver to further compress spring 106.

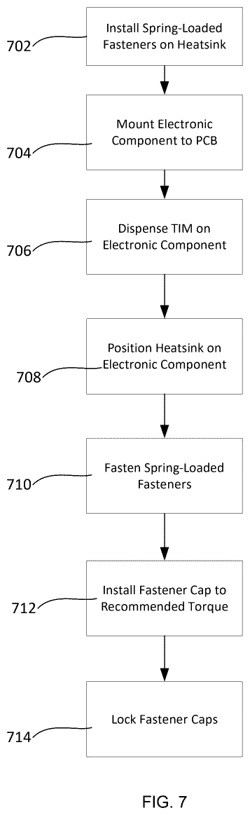

FIG. 7 is a flowchart illustrating one embodiment of a method for installing multi-stage, spring-loaded fastener assembly 100. At step 702, spring-loaded fasteners are installed on a heatsink. According to one embodiment, each spring-loaded fastener is installed with a respective fastener 102 passing through a respective compression spring 106, pressure plate 108 and opening in heatsink base 56. Retaining member 110 can be used to retain the spring-loaded fastener 102 in the hole of heatsink base 56 (see, FIG. 7).

At step 704, an electronic component is placed on a PCB (e.g., PCB 58). The PCB or a PCB backplane has fastener receivers installed at locations about the electronic component. At step 706, a thermally conductive material (TIM) is dispensed on the component. At step 708, the heatsink is placed on the electronic component with the spring-loaded fasteners aligned with the fastener receivers.

At step 710, the spring-loaded fasteners are fastened to the respective receivers. According to one embodiment, each spring-loaded fastener 102 is engaged with a respective fastener receiver 112 until it bottoms out, thus compressing the respective compression spring 106 a desired amount to assert a desired force on pressure plates 108 and hence heatsink base 56. The respective pressure plate 108 acts to distribute the force asserted by spring 106 over a greater area. Step 710 may be repeated for each spring-loaded fastener of the heatsink.

At step 712 fastener caps 104 are installed. According to one embodiment, a respective fastener cap 104 is threaded onto a respective fastener head 114 and driven with a torque wrench until a desired torque is reached. Step 712 may be repeated for each spring-loaded fastener of the heatsink. In some embodiments, thread glue or other mechanism is used to lock the fastener caps 104 relative to the fasteners 102 (step 714).

FIG. 7 is merely illustrative and the disclosed subject matter is not limited to the ordering or number of steps illustrated. Embodiments may implement additional steps or alternative steps, omit steps, or repeat steps.

In this disclosure, specific embodiments have been described with reference to the accompanying figures. In the above description, numerous details are set forth as examples. It will be understood by those skilled in the art, and having the benefit of this Detailed Description, that one or more embodiments described herein may be practiced without these specific details and that numerous variations or modifications may be possible without departing from the scope of the embodiments. Certain details known to those of ordinary skill in the art may be omitted to avoid obscuring the description.

In the above description of the figures, any component described with regard to a figure, in various embodiments, may be equivalent to one or more like-named components shown and/or described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments described herein, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively coupled means that there exists between elements/components/devices a direct or indirect connection that allows the elements to interact with one another in some way. For example, a first component may be operatively connected to a second component to assert a force on the second component by being connected to the second component through one or more intermediate structures that transfer the force between the first component and the second component.

While embodiments described herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. A fastener apparatus, comprising:
a fastener cap adapted to be installed on a spring-loaded fastener, the fastener cap comprising:
a head portion; and
a body portion extending from the head portion in a first direction, the body portion adapted to extend toward a pressure plate and resist movement in a second direction that is opposite to the first direction, wherein the spring-loaded fastener comprises:
a fastener head;
a fastener body that extends from the fastener head to a distal end;
a pressure plate; and
a compression spring disposed between the fastener head and the pressure plate to assert a force on the pressure plate, wherein the fastener cap is adapted to installed on the spring-loaded fastener with the body portion of the fastener cap extending toward and operatively coupled to the pressure plate to resist motion of the pressure plate in a second direction that is opposite of the first direction.

2. The fastener apparatus of claim 1, wherein the fastener cap defines a cavity, wherein the fastener cap is adapted to be installed on the spring-loaded fastener with the compression spring and a portion of the fastener body disposed in the cavity.

3. The fastener apparatus of claim 1, wherein the fastener cap is adapted to be installed on the spring-loaded fastener with the fastener cap is spaced from the fastener body and the compression spring disposed between the fastener body and the fastener cap.

4. The fastener apparatus of claim 3, wherein the body portion of the fastener cap comprises a cylindrical wall and wherein the fastener cap is adapted to be installed on the spring-loaded fastener with the cylindrical wall disposed about a portion of the fastener body.

5. The fastener apparatus of claim 1, wherein the fastener head comprises external threads and wherein the head portion of the fastener cap comprises internal threads adapted to engage with the external threads of the fastener head.

6. The fastener apparatus of claim 5, wherein the fastener cap defines an opening in which the internal threads are disposed and through which the fastener head can be accessed when the fastener cap is installed.

7. The fastener apparatus of claim 5, wherein the fastener cap comprises an outer profile adapted to be received by a second tool.

8. A multi-stage, spring-loaded fastener kit, comprising:
a fastener comprising:
a fastener head; and
a fastener body that extends from the fastener head to a distal end;
a pressure plate having an opening sized to allow the fastener body to pass;
a compression spring sized to fit over the fastener body and be compressed between the fastener and the pressure plate to assert a force in a first direction on the pressure plate; and
a fastener cap, the fastener cap comprising:
a head portion; and
a body portion extending from the head portion, wherein the fastener cap is adapted to be installed on the fastener with the body portion extending toward and operatively coupled to the pressure plate to resist motion of the pressure plate in a second direction that is opposite of the first direction.

9. The multi-stage, spring-loaded fastener kit of claim 8, wherein the body portion of the fastener cap is adapted to fit over a portion of the fastener body and the compression spring.

10. The multi-stage, spring-loaded fastener kit of claim 8, wherein the fastener body has an outer diameter and wherein the body portion of the fastener cap has an inner diameter that is greater than outer diameter of the fastener body to create a gap between the fastener body and the body portion of the fastener cap when the fastener cap is installed.

11. The multi-stage, spring-loaded fastener kit of claim 8, wherein the body portion of the fastener cap comprises a cylindrical wall that is shorter than the fastener body.

12. The multi-stage, spring-loaded fastener kit of claim 8, wherein the fastener head comprises external threads and wherein the head portion of the fastener cap comprises internal threads adapted to engage with the external threads of the fastener head.

13. The multi-stage, spring-loaded fastener kit of claim 12, wherein the fastener cap defines a threaded opening in which the internal threads are disposed, wherein the fastener head is accessible through the threaded opening when the fastener cap is installed.

14. The multi-stage, spring-loaded fastener kit of claim 12, wherein the fastener head defines a shaped recess to receive a first tool and wherein the head portion of the fastener cap comprises an outer profile adapted to be received by a second tool.

15. A method for securing a heat management component, comprising:
coupling a fastener cap to a spring-loaded fastener, the fastener cap comprising:
a head portion adapted to couple to the spring-loaded fastener; and
a body portion extending in a first direction; and
driving the fastener cap to operatively couple the body portion to a pressure plate to resist movement of the pressure plate in a second direction that is opposite to the first direction;
wherein the spring-loaded fastener is installed on a heatsink to hold the heatsink in a position relative to an electronic component, the spring-loaded fastener comprising:
a fastener head;
a fastener body that extends from the fastener head to a distal end;
the pressure plate; and
a compression spring disposed between the fastener head and the pressure plate; and
wherein the spring-loaded fastener is fastened to a fastener receiver to compress the compression spring, wherein the compression spring asserts a force on the pressure plate on the heatsink in a first direction.

16. The method of claim 15, wherein installing the fastener cap on the spring-loaded fastener comprises driving the fastener cap until a specified torque is reached.

17. The method of claim 15, wherein the fastener head comprises external threads, wherein the head portion of the fastener cap comprises internal threads, and wherein coupling the fastener cap to the spring-loaded fastener comprises engaging the internal threads of the head portion of the fastener cap with the external threads of the fastener head.

18. The method of claim 15, wherein spring-loaded fastener is fastened to the fastener receiver to bias the heatsink toward the electronic component to compress a thermal interface material.

19. The method of claim 15, wherein driving the fastener cap comprises rotating the fastener cap in a same rotational direction as used to fasten the spring-loaded fastener.

20. The method of claim 15, further comprising locking the fastener cap to the spring-loaded fastener with thread glue.
